(19) United States
(12) Patent Application Publication
(10) Pub. No.: US 2025/0372944 A1
(43) Pub. Date: Dec. 4, 2025

(54) SEMICONDUCTOR LASER ELEMENT, AND LIGHT SOURCE DEVICE USING SEMICONDUCTOR LASER ELEMENT

(71) Applicants: NICHIA CORPORATION, Anan-shi (JP); KYOTO UNIVERSITY, Kyoto-shi (JP)

(72) Inventors: Natsuo TAGUCHI, Tokushima-shi (JP); Susumu NODA, Kyoto-shi (JP)

(73) Assignees: NICHIA CORPORATION, Anan-shi (JP); KYOTO UNIVERSITY, Kyoto-shi (JP)

(21) Appl. No.: 19/219,436

(22) Filed: May 27, 2025

(30) Foreign Application Priority Data
May 31, 2024 (JP) 2024-089434

(51) Int. Cl. H01S 5/042; H01S 5/11

(52) U.S. Cl. CPC H01S 5/04256; H01S 5/11

(57) ABSTRACT

A semiconductor laser element includes: a semiconductor layered body including a first semiconductor layer, a second semiconductor layer, and an active layer; a first electrode; a second electrode; and a third electrode. One or both of the first semiconductor layer and the second semiconductor layer have a two-dimensional photonic crystal region and a non-two-dimensional photonic crystal region. The two-dimensional photonic crystal region has a two-dimensional periodic structure in which, in a first medium having a first refractive index, second media having a second refractive index different from the first refractive index are two-dimensionally and periodically arranged. The non-two-dimensional photonic crystal region does not have a periodic structure. The second electrode overlaps, among boundary regions defining a boundary between the two-dimensional photonic crystal region and the non-two-dimensional photonic crystal region, at least a boundary region that is orthogonal to one of diffraction directions determined by the two-dimensional periodic structure.

### CROSS-REFERENCE TO RELATED APPLICATIONS

This application is based on and claims priority to Japanese Patent Application No. 2024-089434, filed on May 31, 2024, the entire contents of which are incorporated herein by reference.

### BACKGROUND

### 1. Technical Field

The present disclosure relates to a semiconductor laser element, and a light source device using the semiconductor laser element.

### 2. Description of Related Art

A two-dimensional photonic crystal surface emitting laser (PCSEL) has been proposed (see PCT Publication No. WO2016/031966, for example). In such a PCSEL, a resonance mode determined by a two-dimensional periodicity of a photonic crystal is formed, and high-output single-mode oscillation is possible. A high-output PCSEL operating in both a single longitudinal mode and a single transverse mode has high beam quality, and is expected to be used in various fields such as remote sensing, laser processing, and optical communication.

### SUMMARY

There are cases where it is desirable to use a secondary beam according to an application of a semiconductor laser element. In one aspect of the present disclosure, a semiconductor laser element can be provided in which turning on and off of secondary beams are controllable.

According to one embodiment of the present disclosure, a semiconductor laser element includes: a semiconductor layered body including a first semiconductor layer on a first conductivity side, a second semiconductor layer on a conductivity side opposite to the first conductivity side, and an active layer disposed between the first semiconductor layer and the second semiconductor layer; a first electrode and a second electrode that are separated from each other and electrically connected to the second semiconductor layer; and a third electrode electrically connected the first semiconductor layer. One or both of the first semiconductor layer and the second semiconductor layer have a two-dimensional photonic crystal region and a non-two-dimensional photonic crystal region. The two-dimensional photonic crystal region has a two-dimensional periodic structure in which, in a first medium having a first refractive index, second media having a second refractive index different from the first refractive index are two-dimensionally and periodically arranged. The non-two-dimensional photonic crystal region does not have a periodic structure and is disposed outward of the two-dimensional photonic crystal region. The first electrode is located inward of the two-dimensional photonic crystal region in a plan view. The second electrode overlaps, among boundary regions defining a boundary between the two-dimensional photonic crystal region and the non-two-dimensional photonic crystal region, at least a boundary region that is orthogonal to one of diffraction directions determined by the two-dimensional periodic structure.

### BRIEF DESCRIPTION OF THE DRAWINGS

FIG. 1 is a schematic cross-sectional view of a semiconductor laser element according to an embodiment;

FIG. 2 is a diagram illustrating an example of a two-dimensional periodic structure of a two-dimensional photonic crystal region;

FIG. 3 is a diagram illustrating another example of a two-dimensional periodic structure of the two-dimensional photonic crystal region;

FIG. 4 is a diagram illustrating an example of an electrode arrangement when a two-dimensional periodic structure of a triangular lattice is used;

FIG. 5 is a diagram illustrating an example of an electrode arrangement when a two-dimensional periodic structure of a square lattice is used;

FIG. 6 is a schematic diagram of an excitation spot in a two-dimensional photonic crystal region having a quadrangular shape;

FIG. 7 illustrates a far field pattern (FFP) and a near field pattern (NFP) when the spot diameter of excitation light is 300 μm;

FIG. 8 illustrates an FFP and an NFP when the spot diameter of the excitation light is 1,000 μm;

FIG. 9 is a schematic diagram of an excitation spot in a two-dimensional photonic crystal region having a circular shape;

FIG. 10 illustrates an FFP and an NFP when the spot diameter of excitation light is 300 μm;

FIG. 11 illustrates an FFP and an NFP when the spot diameter of the excitation light is 1,000 μm;

FIG. 12 is a schematic diagram illustrating excitation positions in a two-dimensional photonic crystal region;

FIG. 13 illustrates an FFP and an NFP when excitation occurs at a position P1;

FIG. 14 illustrates an FFP and an NFP when excitation occurs at a position P2;

FIG. 15 illustrates an FFP and an NFP when excitation occurs at a position P3;

FIG. 16 illustrates an FFP and an NFP when excitation occurs at a position P4;

FIG. 17 illustrates an FFP and an NFP when excitation occurs at a position P5;

FIG. 18 is a diagram illustrating an example of the arrangement of an electrode for current injection;

FIG. 19 is a diagram illustrating another example of the arrangement of electrodes for current injection;

FIG. 20 is a diagram illustrating yet another example of the arrangement of electrodes for current injection;

FIG. 21 is a schematic cross-sectional view of a light source device using the semiconductor laser element according to the embodiment;

FIG. 22A is a diagram illustrating a process of manufacturing a semiconductor laser element;

FIG. 22B is a diagram illustrating the process of manufacturing the semiconductor laser element;

FIG. 22C is a diagram illustrating the process of manufacturing the semiconductor laser element;

FIG. 22D is a diagram illustrating the process of manufacturing the semiconductor laser element; and

FIG. 22E is a diagram illustrating the process of manufacturing the semiconductor laser element.

### DETAILED DESCRIPTION

In an embodiment, a two-dimensional photonic crystal region having a two-dimensional periodic structure is provided in a semiconductor laser of a semiconductor laser element, and a non-two-dimensional photonic crystal region having no periodic structure is disposed outward of the two-dimensional photonic crystal region. A first electrode is disposed inward of the two-dimensional photonic crystal region in a plan view, and a second electrode is disposed so as to overlap at least a portion of a boundary between the two-dimensional photonic crystal region and the non-two-dimensional photonic crystal region in the same plane as the first electrode. The first electrode and the second electrode are separated from each other and electrically connected to the same semiconductor layer. The second electrode overlaps, among boundary regions defining the boundary between the two-dimensional photonic crystal region and the non-two-dimensional photonic crystal region, at least a boundary region that is orthogonal to one of a plurality of diffraction directions determined by the two-dimensional periodic structure. Secondary beams are controlled to be individually turned on or off by controlling supply of electricity to the first electrode and the second electrode.

Embodiments of the present disclosure will be described below with reference to the accompanying drawings. The following description is provided for the purpose of embodying the technical ideas of the present disclosure, but the present disclosure is not limited to the embodiments in the following description unless specifically stated. In the drawings, members having the same functions may be denoted by the same reference numerals. In consideration of ease of explanation or ease of understanding of main points, configurations may be illustrated in separate embodiments for the sake of convenience; however, such configurations illustrated in different embodiments or examples can be partially substituted or combined with one another. A description of an embodiment given after a description of another embodiment will be focused mainly on matters different from those of the previously described embodiment, and a duplicate description of matters common to the previously described embodiment may be omitted. The sizes, positional relationships, and the like of members illustrated in the drawings may be exaggerated for clearer illustration.

### <Configuration of Semiconductor Laser Element>

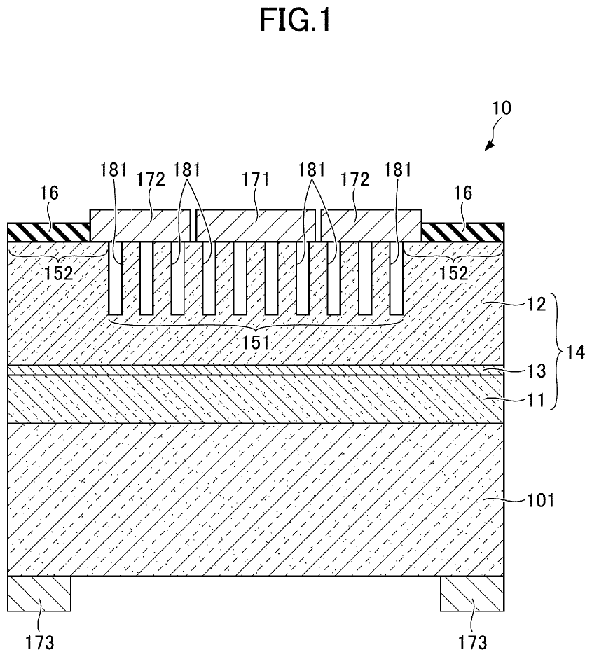

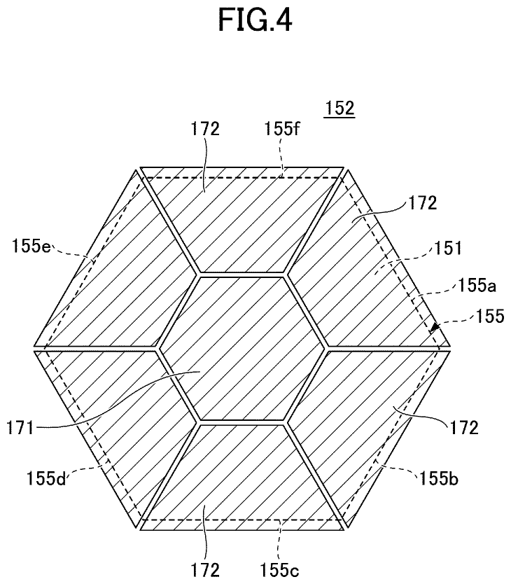

FIG. 1 is a schematic cross-sectional view of a semiconductor laser element 10 according to an embodiment. The semiconductor laser element 10 includes a semiconductor layered body 14 including a first semiconductor layer 11 on a first conductivity side, a second semiconductor layer 12 on a conductivity side opposite to the first conductivity side, and an active layer 13 disposed between the first semiconductor layer 11 and the second semiconductor layer 12. The semiconductor laser element 10 includes a first electrode 171 and a second electrode 172 that are separated from each other and electrically connected to the second semiconductor layer 12, and includes a third electrode 173 electrically connected to the first semiconductor layer 11. One or both of the first semiconductor layer 11 and the second semiconductor layer 12 have a two-dimensional photonic crystal region 151 and a non-two-dimensional photonic crystal region 152. The two-dimensional photonic crystal region 151 has a two-dimensional periodic structure in which, in a first medium having a first refractive index, second media having a second refractive index different from the first refractive index are two-dimensionally and periodically arranged. The non-two-dimensional photonic crystal region 152 does not have a periodic structure and is disposed outward of the two-dimensional photonic crystal region 151. The first electrode 171 is located inward of the two-dimensional photonic crystal region 151 in a plan view, and the second electrode 172 overlaps, among boundary regions defining a boundary between the two-dimensional photonic crystal region 151 and the non-two-dimensional photonic crystal region 152, at least a boundary region that is orthogonal to one of a plurality of diffraction directions determined by the two-dimensional periodic structure. The arrangement of the first electrode 171 and the second electrode 172 will be described below with reference to FIG. 4 and FIG. 5.

In the example configuration of FIG. 1, the first semiconductor layer 11 is, for example, an n-side semiconductor layer, and the second semiconductor layer 12 is a p-side semiconductor layer. The first electrode 171 is a first positive electrode, the second electrode 172 is a second positive electrode, and the third electrode 173 is a negative electrode. The second semiconductor layer 12, which is the p-side semiconductor layer, has the two-dimensional photonic crystal region 151 and the non-two-dimensional photonic crystal region 152. Thus, the two-dimensional photonic crystal region 151 can be provided in the second semiconductor layer (that is, the p-side semiconductor layer) after the semiconductor layered body 14 is formed. As compared to a case in which the two-dimensional photonic crystal region 151 is formed during the formation of the semiconductor layered body 14, a positional deviation between the active layer 13 directly under the two-dimensional photonic crystal region 151 and the active layer 13 directly under the non-two-dimensional photonic crystal region 152 is less likely to occur. A period of the two-dimensional photonic crystal region 151 can be adjusted in accordance with the gain of the semiconductor layered body 14. As the second electrode 172, one or more electrodes are provided. For example, the second electrode 172 includes two or more second electrodes 172 spaced apart from each other, and each of the two or more second electrodes 172 overlaps a corresponding one of boundary regions orthogonal to diffraction directions. Accordingly, secondary beams can be effectively extracted.

The semiconductor layered body 14 including the first semiconductor layer 11, the active layer 13, and the second semiconductor layer 12 is provided on a substrate 101; however, the substrate 101 may be polished or removed after the semiconductor layered body 14 is grown and before the third electrode 173 is formed. The first semiconductor layer 11, the active layer 13, and the second semiconductor layer 12 are nitride semiconductor layers. In the example of FIG. 1, an n-side GaN layer as the first semiconductor layer 11, and a p-side GaN layer as the second semiconductor layer 12, are disposed on a GaN substrate containing an n-type impurity. The active layer 13 disposed between the first semiconductor layer 11 and the second semiconductor layer 12 has, for example, a multiple quantum well structure of In_{y}Ga_{1-y}N (0≤y≤1). Each of the first semiconductor layer 11 and the second semiconductor layer 12 may include a plurality of types of layers such as a cladding layer and a contact layer. Each of the first semiconductor layer 11 and the second semiconductor layer 12 may be, for example, AlₓGa₁₋ₓN (0≤x≤1).

In FIG. 1, the two-dimensional photonic crystal region 151 and the non-two-dimensional photonic crystal region 152 are provided in the second semiconductor layer 12, which is the p-side semiconductor layer. However, the two-dimensional photonic crystal region 151 and the non-two-dimensional photonic crystal region 152 may be provided in the n-side semiconductor layer depending on a device design. The surface of the non-two-dimensional photonic crystal region 152 may be protected by an insulating layer 16. Light generated in the active layer 13 by carrier recombination is affected by various diffraction effects caused by the two-dimensional periodic structure of the two-dimensional photonic crystal region 151 and forms a resonance mode. For example, by forming a two-dimensional periodic pattern of second media having a refractive index different from the refractive index of a first medium, which is a nitride semiconductor, in the first medium, the two-dimensional photonic crystal region 151 is formed in the vicinity of the active layer 13. In the example of FIG. 1, recesses 181 are formed in a predetermined period in an in-plane direction of the second semiconductor layer 12, and air is used as the second media. Alternatively, the inside of the recesses 181 may be filled with a medium other than air having a refractive index different from the refractive index of the second semiconductor layer 12. Examples of the second media other than air include SiO₂, TiO₂, Al₂O₃, Nb₂O₅, Ta₂O₅, SiN, SiON, and the like.

Among lights propagating in the in-plane direction within the two-dimensional photonic crystal region 151, light having a wavelength equal to the period of the two-dimensional periodic structure resonates, and the phases are synchronized in the entire two-dimensional photonic crystal region 151, thereby generating a standing wave. The two-dimensional periodic structure of the two-dimensional photonic crystal region 151 is, for example, a square lattice structure or a triangular lattice structure. Light forming a standing wave and having a wavelength equal to the two-dimensional period of the two-dimensional photonic crystal region 151 is also diffracted in a direction perpendicular to the crystal plane, and the semiconductor laser element 10 operates as a surface emitting laser. In the configuration of FIG. 1, laser light is generated in both a direction from the active layer 13 toward the first semiconductor layer 11 and a direction from the active layer 13 toward the second semiconductor layer 12. However, the laser light is reflected by the first electrode 171 and the second electrode 172, and the laser light is emitted from the back surface of the substrate 101 on which the third electrode 173 is provided. In the layered direction of the semiconductor laser element 10, the first semiconductor layer 11 and the second semiconductor layer 12 confine light due to the difference in refractive index with respect to the active layer 13, and in the in-plane direction, the two-dimensional periodic structure of the two-dimensional photonic crystal region 151 serves to confine light.

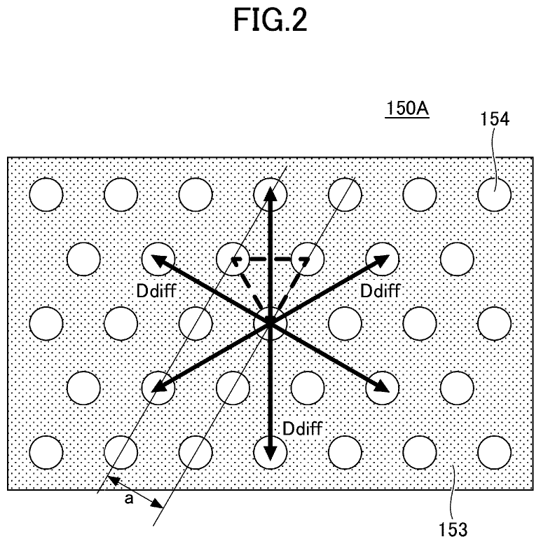

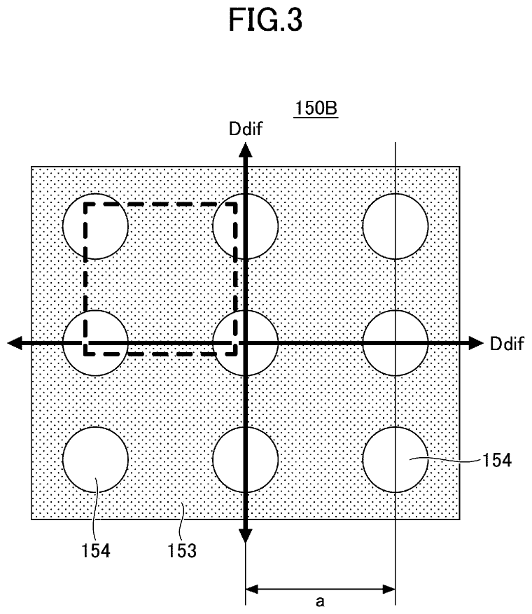

FIG. 2 and FIG. 3 are diagrams illustrating examples of two-dimensional periodic structures of the two-dimensional photonic crystal region 151 (see FIG. 1). A two-dimensional periodic structure 150A of FIG. 2 has second media 154 that are arranged in a triangular lattice in a first medium 153. Each of the second media 154 serves as a vertex of a triangle, and triangles sharing sides are connected in a two-dimensional plane. An interval between lattice planes is a lattice constant “a” of a photonic crystal of the triangular lattice, that is, a period. The lattice constant “a” of the triangular lattice is determined according to the wavelength of laser light to be generated, and is, for example, in a range of 0.1 μm to 2.0 μm. The diameter of each of the second media 154 is, for example, 0.1 times or more and 1.15 times or less, preferably 0.1 times or more and 0.5 times or less, the lattice constant “a”. This balances the proportion of light affected by the two-dimensional photonic crystal and the coupling coefficient, and thus surface emission can be efficiently obtained. When the triangular lattice is a regular triangular lattice, it is also called a hexagonal lattice. Diffraction directions Ddif of the triangular lattice are six directions obtained by dividing 360 degrees around a certain lattice point into six equal parts as indicated by thick arrows.

A two-dimensional periodic structure 150B of FIG. 3 has second media 154 that are arranged in a square lattice in the first medium 153. Each of the second media 154 serves as a vertex of a square, and squares sharing sides are connected in a two-dimensional plane. An interval between lattice planes is a lattice constant “a” of a photonic crystal of the square lattice, that is, a period. The lattice constant “a” of the square lattice is determined according to the wavelength of laser light to be generated, and is, for example, in a range of 0.1 μm to 2.0 μm. The diameter of each of the second media 154 is in a range of, for example, 0.1 times to 0.7 times the lattice constant “a”. Diffraction directions Ddif of the square lattice are four directions orthogonal to each other and extending from a certain lattice point to four adjacent lattice points as indicated by thick arrows.

In each of the examples of FIG. 2 and FIG. 3, the second media 154 each have a planar form that is a circular shape, and cylindrical air holes are formed as the recesses 181 illustrated in FIG. 1; however, the configuration is not limited to this example. As the second media 154, holes or protrusions each having a planar form that is a triangular shape, a quadrangular shape, a hexagonal shape, an elliptical shape, or the like may be formed. The two-dimensional periodic structure 150A or 150B is not limited to the triangular lattice or the square lattice, and a lattice pattern such as a rectangular lattice or a rhombic lattice may be employed according to the application. The non-two-dimensional photonic crystal region 152 having no periodic structure is disposed outward of the two-dimensional photonic crystal region 151 having such a two-dimensional periodic structure. In a plan view, a boundary between the two-dimensional photonic crystal region 151 and the non-two-dimensional photonic crystal region 152 is, for example, a line connecting the outermost peripheries of second media 154 among second media 154 forming a two-dimensional periodic structure. In a three-dimensional lattice structure, if each of the second media 154 has a circular shape in a plan view, a surface that circumscribe outermost ones of cylindrical holes serve as a boundary perceived by a standing wave.

In a plan view, the shape of the two-dimensional photonic crystal region 151 having a two-dimensional periodic structure is a circle having a circumference orthogonal to a diffraction direction Ddif or a polygon having a side orthogonal to a diffraction direction Ddif. In a case where the two-dimensional periodic structure is the triangular lattice structure, the shape of the two-dimensional photonic crystal region 151 in a plan view may be a circle having a circumference to which a tangent line orthogonal to one of the diffraction directions Ddif determined by the triangular lattice is drawable, or a polygon having a side orthogonal to one of the diffraction directions Ddif determined by the triangular lattice. With this configuration, a secondary beam can be efficiently obtained. In a case where the two-dimensional periodic structure is the square lattice structure, the shape of the two-dimensional photonic crystal region 151 in a plan view is a circle having a circumference to which a tangent line orthogonal to one of the diffraction directions Ddif determined by the square lattice is drawable, or a polygon having a side orthogonal to one of the diffraction directions Ddif determined by the square lattice. With this configuration, a secondary beam can be efficiently obtained. A secondary beam is extracted by utilizing a boundary surface between a semiconductor layer formed of the first medium 153 and a second medium 154 located in the vicinity of the outermost periphery of the two-dimensional photonic crystal region 151 having such a shape in a plan view. Therefore, the second electrode 172 is provided so as to overlap at least a boundary region that is orthogonal to a diffraction direction among boundary regions defining the boundary between the two-dimensional photonic crystal region 151 and the non-two-dimensional photonic crystal region 152 in a plan view.

FIG. 4 is a diagram illustrating an example of an electrode arrangement when a two-dimensional periodic structure of a triangular lattice is used. FIG. 5 is a diagram illustrating an example of an electrode arrangement when a two-dimensional periodic structure of a square lattice is used. A first electrode 171 and a second electrode 172 are separated from each other and electrically connected to the second semiconductor layer 12 (see FIG. 1) in which a two-dimensional photonic crystal region 151 is formed. In the example of FIG. 4, a non-two-dimensional photonic crystal region 152 is disposed outward of a two-dimensional photonic crystal region 151 having a hexagonal shape in a plan view. A first electrode 171 is provided inward of the two-dimensional photonic crystal region 151 in a plan view. A second electrode 172 overlaps at least one of boundary regions 155a to 155f that are orthogonal to diffraction directions determined by the two-dimensional periodic structure and that define a boundary 155 between the two-dimensional photonic crystal region 151 and the non-two-dimensional photonic crystal region 152. The diffraction directions determined by the triangular lattice of FIG. 4 are six directions obtained by dividing 360 degrees around a certain lattice point into six equal parts as illustrated in FIG. 2. The second electrode 172 is disposed so as to overlap at least one side of the two-dimensional photonic crystal region 151 having the hexagonal shape with sides orthogonal to the six diffraction directions.

In the example configuration of FIG. 4, the second electrode 172 includes six second electrodes 172 separated from each other, and the six second electrodes 172 overlap the respective boundary regions 155a to 155f that are orthogonal to the diffractive directions. Accordingly, secondary beams can be efficiently generated by current excitation. The second electrodes 172 may overlap the two-dimensional photonic crystal region 151 outward of the first electrode 171 as viewed from the center of the two-dimensional photonic crystal region 151. Accordingly, the two-dimensional photonic crystal region 151 can be excited to generate a secondary beam even by current excitation with a second electrode alone.

Referring to FIG. 5, a non-two-dimensional photonic crystal region 152 is disposed outward of a two-dimensional photonic crystal region 151 having a square shape in a plan view. A first electrode 171 is located inward of the two-dimensional photonic crystal region 151 in a plan view. A second electrode 172 overlaps at least one of boundary regions 155g to 155j that are orthogonal to diffraction directions determined by the two-dimensional periodic structure and that define a boundary 155 between the two-dimensional photonic crystal region 151 and the non-two-dimensional photonic crystal region 152. In the case of a square lattice, the diffraction directions determined by the square lattice are four directions extending from a certain lattice point and perpendicular to each other as illustrated in FIG. 3. The second electrode 172 is disposed so as to overlap at least one side of the two-dimensional photonic crystal region 151 having the square shape with sides orthogonal to the four diffraction directions.

In the example configuration in FIG. 5, the second electrode 172 includes four second electrodes 172 separated from each other, and the four second electrodes 172 overlap the respective boundary regions 155g to 155j that are orthogonal to the diffractive directions. Accordingly, a secondary beam can be efficiently generated by current excitation. The second electrodes 172 may overlap the two-dimensional photonic crystal region 151 outward of the first electrode 171 with respect to the center of the two-dimensional photonic crystal region 151. Accordingly, the two-dimensional photonic crystal region 151 can be excited to generate a secondary beam even by current excitation with a second electrode alone.

The number of divided second electrodes 172 is not limited to four or six, and two or more second electrodes 172 may be included. One first electrode 171 and one second electrode 172 may be disposed or one first electrode 171 and two or more second electrodes 172 may be disposed according to the application of the semiconductor laser element 10. The two or more second electrodes 172 are not necessarily arranged along the entire periphery of the first electrode 171; in some cases, they are arranged only at positions where secondary beams are to be emitted.

A second electrode 172 overlaps the non-two-dimensional photonic crystal region 152 by a predetermined width from a boundary region. The predetermined width is, for example, 0.1% or more and 50% or less of the length of a perpendicular line drawn from the center of the two-dimensional photonic crystal region 151 to a corresponding boundary region of the boundary regions 155a to 155f or 155g to 155j in a plan view. Alternatively, the second electrode 172 may overlap the non-two-dimensional photonic crystal region 152 by a width that is two times or more and ten times or less the lattice constant “a” of the two-dimensional photonic crystal region 151. This is because, as will be described below, diffraction light of a secondary beam is extracted by using the outermost peripheral surface of a second medium 154 located in the vicinity of the outermost periphery of the two-dimensional photonic crystal region 151. If the second electrode 172 protrudes excessively outward from a boundary region, current injection loss occurs, and thus it is desirable that the second electrode 172 covers the boundary region by a width corresponding to approximately two periods to ten periods of the two-dimensional photonic crystal lattice. However, the end of the second electrode 172 may be located inward of the two-dimensional photonic crystal region 151 within a manufacturing error range.

By individually controlling a first electrode 171 and a second electrode 172 or individually controlling a plurality of second electrodes 172, light can be emitted only in desired direction(s).

### <Patterns of Diffraction Light Generated by Optical Excitation>

The semiconductor laser element 10 emits light by current excitation using a first electrode 171, a second electrode 172, and a third electrode 173. In particular, light is emitted at desired position(s) by individually controlling supply of electricity to the first electrode 171 and the second electrode 172 or by individually controlling supply of electricity to each of a plurality of divided second electrodes. This principle of driving the semiconductor laser element 10 will be described by using patterns of diffraction light obtained by optically exciting the two-dimensional photonic crystal region 151.

### <Two-Dimensional Photonic Crystal Region Having Quadrangular Shape>

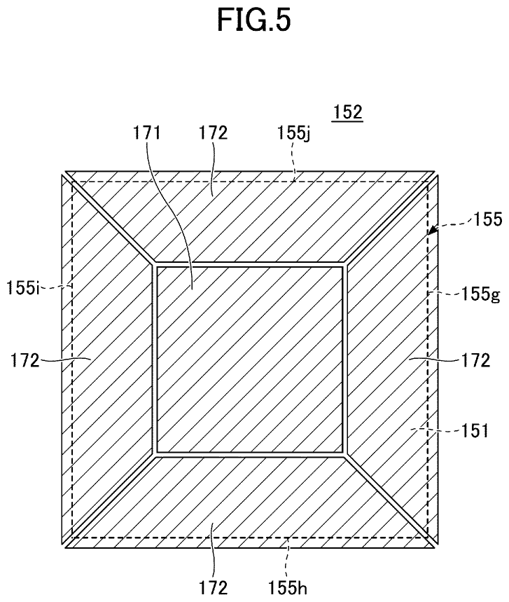

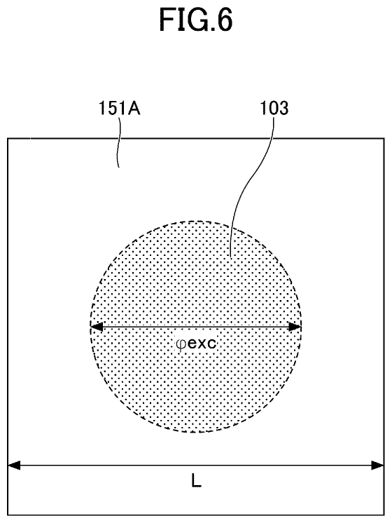

FIG. 6 is a schematic diagram of an excitation spot 103 in a two-dimensional photonic crystal region 151A having a quadrangular shape. First, a sample of the semiconductor laser element 10 having a two-dimensional periodic structure is produced. This sample has the two-dimensional photonic crystal region 151A having a triangular lattice arrangement in its quadrangular-shaped region. Diffraction directions of the triangular lattice arrangement are six directions obtained by dividing 360 degrees into six equal parts. A region outward of the two-dimensional photonic crystal region 151A is a non-two-dimensional photonic crystal region having no periodic structure. A length L of one side of the two-dimensional photonic crystal region 151A is 1,000 μm. The two-dimensional photonic crystal region 151A is irradiated with excitation light having a circular cross section to cause laser oscillation. Ultraviolet light having a wavelength of 355 nm is used as the excitation light. A far field pattern (FFP) and a near field pattern (NFP) of generated diffraction light are observed by changing a spot diameter φexc of the excitation light in the two-dimensional photonic crystal region 151A. The excitation spot 103 corresponds to a current injection region in the case of current excitation, that is, an electrode region.

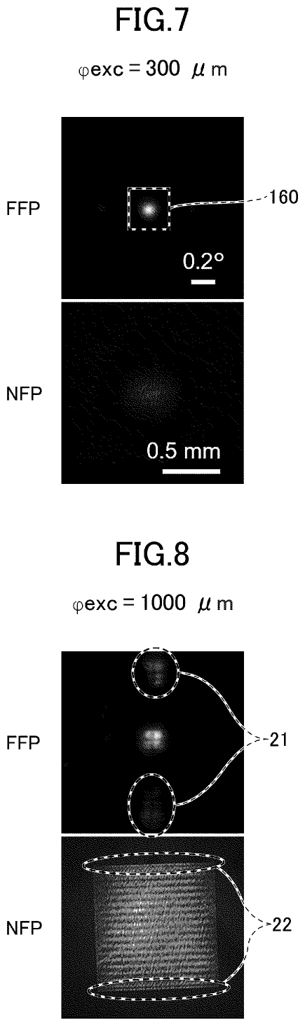

FIG. 7 illustrates an FFP and an NFP when the spot diameter φexc of the excitation light is 300 μm. The NFP is a beam pattern near an exit surface, and the FFP is a beam pattern at a position approximately 30 cm away from the exit surface. A region 160 having a quadrangular shape surrounded by a dotted line in the FFP corresponds to the two-dimensional photonic crystal region 151A. At the center of the region 160, diffraction light emitted from the excitation spot 103 (see FIG. 6) is observed. In the NFP, diffraction light corresponding to the excitation spot 103 is observed on the exit surface, that is, on the surface of the two-dimensional photonic crystal region 151. The beam pattern illustrated in FIG. 7 corresponds to a beam pattern obtained by applying a current to a first electrode 171 disposed at the center of the two-dimensional photonic crystal region 151A.

FIG. 8 illustrates an FFP and an NFP when the spot diameter φexc of the excitation light is 1,000 μm. The excitation spot 103 inscribes the two-dimensional photonic crystal region 151A. Diffraction light is generated at the center of the FFP, and secondary beams 21 are observed at a 12 o'clock position and at a 6 o'clock position. The secondary beams 21 appear in the vicinity of sides perpendicular to corresponding ones of the diffraction directions Ddif (see FIG. 2) determined by the triangular lattice, among the four sides of the quadrangular-shaped two-dimensional photonic crystal region 151A. No secondary beams are observed at a 3 o'clock position nor at a 9 o'clock position where sides of the quadrangular-shaped two-dimensional photonic crystal region 151A are not orthogonal to any of the diffraction directions of the triangular lattice.

In the NFP, it can be seen that light 22 is affected by the boundary of the two-dimensional photonic crystal region 151A orthogonal to the diffraction directions Ddif, that is, the interfaces of second media 154 positioned at the outermost periphery of the triangular lattice arrangement.

The excited region overlaps the outer periphery of the quadrangular-shaped two-dimensional photonic crystal region 151A in the diffraction directions, and thus the secondary beams 21 are output in addition to the diffraction light at the center.

### <Two-Dimensional Photonic Crystal Region Having Circular Shape>

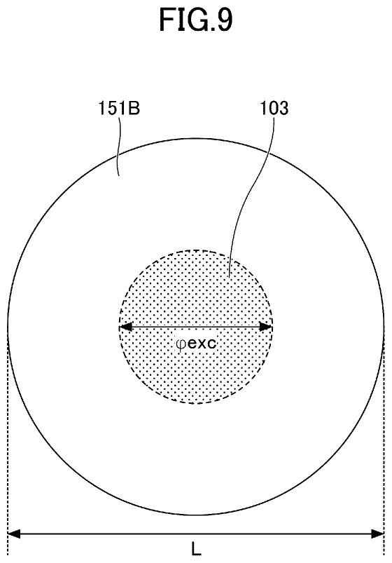

FIG. 9 is a schematic diagram of an excitation spot 103 in a two-dimensional photonic crystal region 151B having a circular shape. Another sample of the semiconductor laser element 10 having a two-dimensional periodic structure is produced. The two-dimensional photonic crystal region 151B of this sample has a triangular lattice arrangement in its circular-shaped region. Diffraction directions of the triangular lattice arrangement are six directions obtained by dividing 360 degrees into six equal parts. A region outward of the two-dimensional photonic crystal region 151B is a non-two-dimensional photonic crystal region having no periodic structure. A diameter L of the two-dimensional photonic crystal region 151B is 1,000 μm. The two-dimensional photonic crystal region 151B is irradiated with excitation light having a circular cross section to cause laser oscillation. Ultraviolet light having a wavelength of 300 nm is used as the excitation light. An FFP and an NFP of generated diffraction light are observed by changing the spot diameter φexc of the excitation light in the two-dimensional photonic crystal region 151B. The excitation spot 103 corresponds to a current injection region in the case of current excitation, that is, an electrode region.

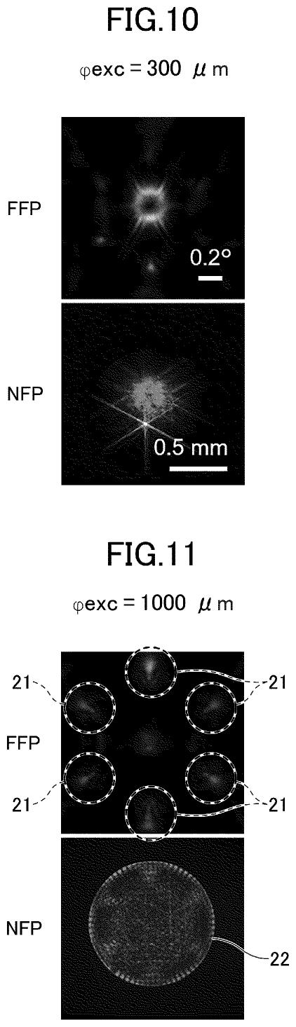

FIG. 10 illustrates an FFP and an NFP when the spot diameter φexc of the excitation light is 300 μm. In the NFP, diffraction light is observed at a position corresponding to the excitation spot 103. In the FFP, in addition to diffraction light at the center, weak diffraction lights are observed at positions corresponding to the vertices of the hexagon. A portion of light generated by optical excitation propagates through the two-dimensional photonic crystal region 151B in a diffraction direction and is diffracted in a direction perpendicular to the two-dimensional periodic plane. In this manner, each of the weak diffraction lights is obtained.

FIG. 11 illustrates an FFP and an NFP when the spot diameter φexc of the excitation light is 1,000 μm. The excitation spot 103 covers the entire two-dimensional photonic crystal region 151B. In the NFP, light 22 spreads over the entire circular-shaped two-dimensional photonic crystal region 151B. In the FFP, six secondary beams 21 are clearly observed in the six diffraction directions determined by the triangular lattice of the two-dimensional photonic crystal region 151B. In the case of the circular-shaped two-dimensional photonic crystal region 151B, the diffractive directions determined by the triangular lattice are perpendicular to tangent lines at the locations of the secondary beams 21.

The measurement results of FIG. 6 to FIG. 11 have led to the theory that a secondary beam is emitted at a desired position by supplying electricity to an electrode overlapping a boundary region that is perpendicular to any of diffraction directions determined by a two-dimensional periodic structure, among boundary regions defining a boundary between a two-dimensional photonic crystal region 151 and a non-two-dimensional photonic crystal region include in the semiconductor laser element 10. In order to demonstrate this theory, a plurality of positions in a two-dimensional photonic crystal region having a triangular lattice are partially optically excited, and generated diffraction light is observed.

### <Evaluation of Two-Dimensional Photonic Crystal Region by Optical Excitation>

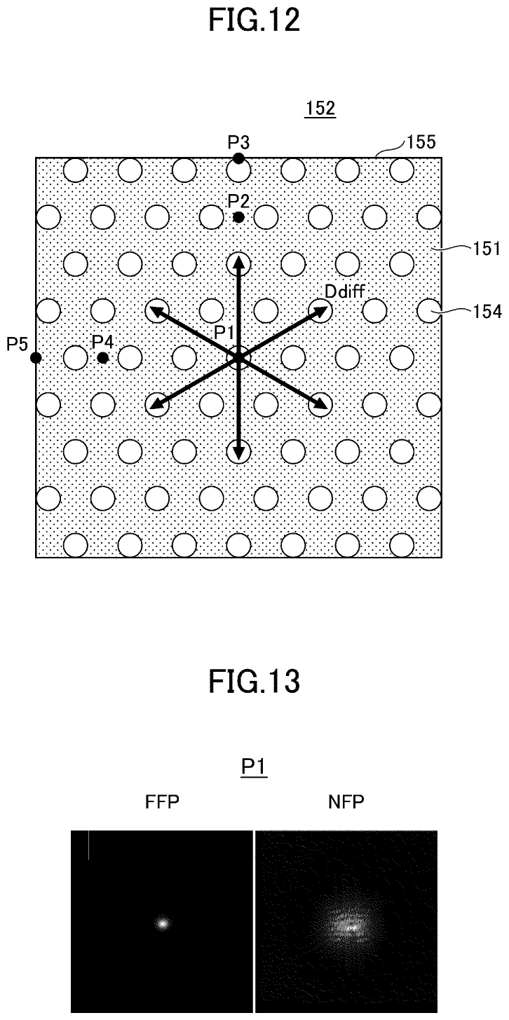

FIG. 12 is a schematic diagram illustrating excitation positions in a two-dimensional photonic crystal region 151. A two-dimensional periodic structure of a triangular lattice is formed within the two-dimensional photonic crystal region 151 having a quadrangular shape in a plan view. A non-two-dimensional photonic crystal region 152 having no periodic structure is disposed outward of the two-dimensional photonic crystal region 151. A boundary 155 between the two-dimensional photonic crystal region 151 and the non-two-dimensional photonic crystal region 152 circumscribes the outermost periphery of the two-dimensional periodic structure. That is, a line circumscribing and surrounding the outermost second media 154 among second media 154 is the boundary 155 between the two-dimensional photonic crystal region 151 and the non-two-dimensional photonic crystal region 152.

Excitation positions P1 to P5 are set in the two-dimensional photonic crystal region 151. Each of the excitation positions P1 to P5 is irradiated with ultraviolet light having a circular beam cross section to cause excitation. FIG. 13 illustrates an FFP and an NFP when excitation occurs at the position P1. The position P1 is located near the center of the two-dimensional photonic crystal region 151. In the FFP, diffraction light is observed only at the center of the two-dimensional photonic crystal region 151. In the NFP, substantially circular diffraction light diffracted in a direction perpendicular to the two-dimensional periodic plane is observed near the center of the two-dimensional photonic crystal region 151.

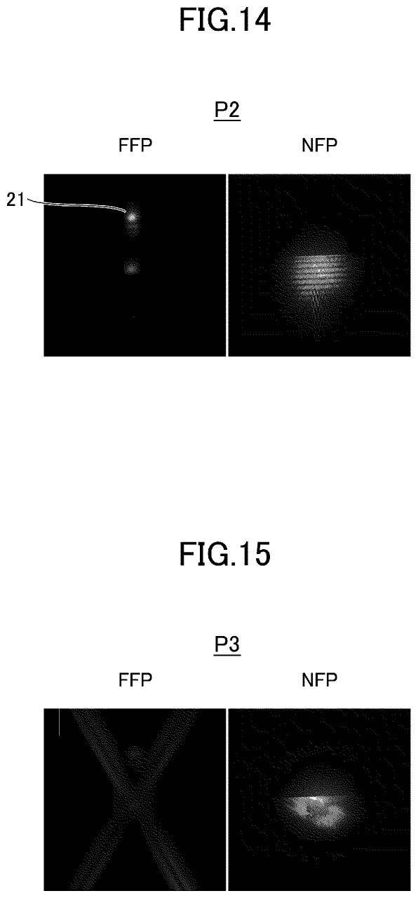

FIG. 14 illustrates an FFP and an NFP when excitation occurs at the position P2. The position P2 is located in one of the diffraction directions determined by the triangular lattice in the two-dimensional photonic crystal region 151. It can be seen that, in the NFP, diffraction light in a stripe shape is observed and the light is affected by the interface of a second medium 154 (see FIG. 2) forming a part of the triangular lattice in the vicinity of the position P2. In this case, as observed in the FFP, a secondary beam 21 is generated at a position corresponding to the excitation position P2.

FIG. 15 illustrates an FFP and an NFP when excitation occurs at the position P3. The position P3 is located on the boundary 155 between the two-dimensional photonic crystal region 151 and the non-two-dimensional photonic crystal region 152. In the NFP, light is affected by the interface of a second medium 154 located on the outermost periphery of the triangular lattice in the vicinity the boundary 155, but no secondary beam is generated in the FFP. Instead, an X-shaped line pattern appears. It is considered that this is because the number of periods of the triangular lattice is insufficient in the vicinity of the boundary 155 between the two-dimensional photonic crystal region 151 and the non-two-dimensional photonic crystal region 152, and thus a secondary beam is less likely to be generated.

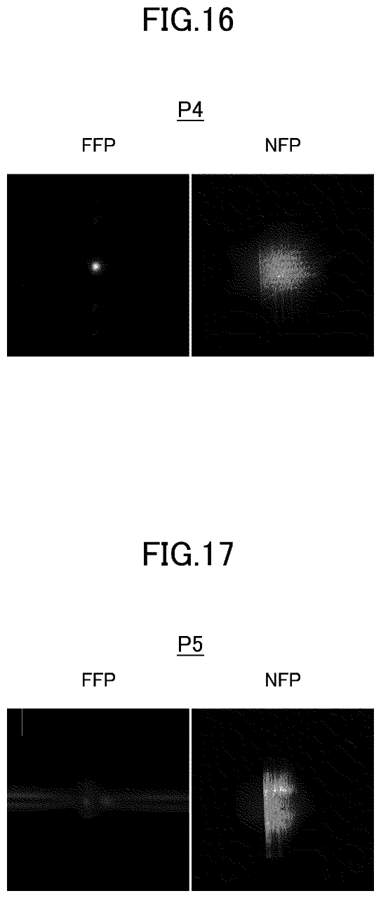

FIG. 16 illustrates an FFP and an NFP when excitation occurs at the position P4. In the NFP, light is affected by the interface of a second medium 154 forming a part of the triangular lattice in the two-dimensional photonic crystal region 151, but no secondary beam is generated at the position P4. It is considered that this is because the position P4 is deviated from any of the diffraction directions determined by the triangular lattice.

FIG. 17 illustrates an FFP and an NFP when excitation occurs at the position P5. The position P5 is located on the boundary 155 between the two-dimensional photonic crystal region 151 and the non-two-dimensional photonic crystal region 152. In the NFP, light is affected by the interface of a second medium 154 located at the outermost periphery of the triangular lattice in the vicinity of the boundary 155, but no secondary beam is generated in the FFP. Instead, a line pattern appears in the horizontal direction. It is considered that this is because of an insufficient number of periods in the vicinity of the boundary 155 between the two-dimensional photonic crystal region 151 and the non-two-dimensional photonic crystal region 152.

From the results illustrated in FIG. 13 to FIG. 17, it was found that a secondary beam can be generated by individually causing excitation at a specific position or a specific region in any of the diffraction directions determined by the two-dimensional periodic structure of the two-dimensional photonic crystal region 151. The semiconductor laser element according to the present embodiment has been made based on this founding, and has been studied for utilizing this phenomenon with current excitation instead of optical excitation. That is, a region into which a current is to be injected is divided by a first electrode 171 and a second electrode 172 such that excitation in the vicinity of the position P1 and excitation in the vicinity of the position P2 in FIG. 12 can be individually performed.

<Performance at Current Injection Predicted from Optical Excitation Evaluation>

Instead of optical excitation, a current is injected by supplying electricity to an electrode electrically connected to the second semiconductor layer 12 (see FIG. 1). As in the case of the optical excitation evaluation, a two-dimensional periodic structure of a triangular lattice is provided in a two-dimensional photonic crystal region 151 having a quadrangular shape.

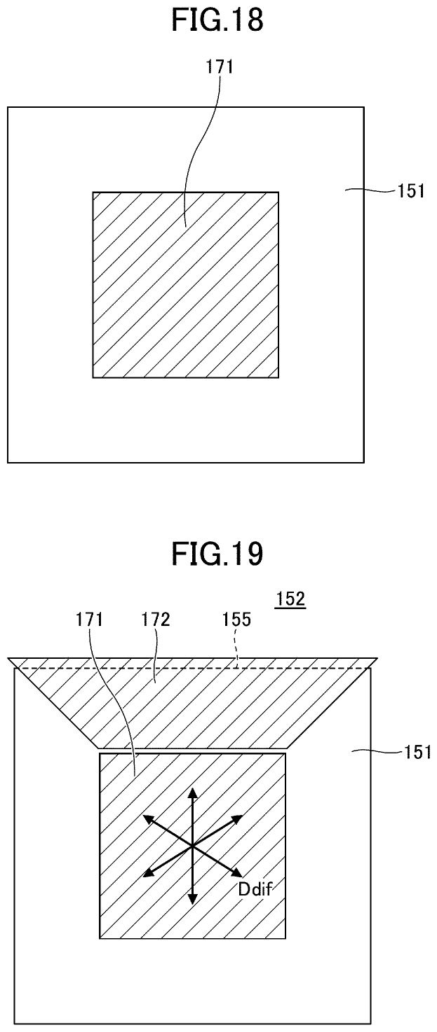

FIG. 18 is a diagram illustrating an example of the arrangement of an electrode for current injection. In FIG. 18, a first electrode 171 having a quadrangular shape is provided in the two-dimensional photonic crystal region 151. This arrangement is a common electrode arrangement. Upon supply of electricity to the first electrode 171, light is output from the center of the two-dimensional photonic crystal region 151 as illustrated in FIG. 13.

FIG. 19 is a diagram illustrating another example of the arrangement of electrodes for current injection. A first electrode 171 having a quadrangular shape is disposed at the center of the two-dimensional photonic crystal region 151. For convenience, the diffraction directions Ddif determined by the triangular lattice forming the two-dimensional photonic crystal region 151 are indicated by black arrows. A second electrode 172 separated from the first electrode 171 covers a portion of the two-dimensional photonic crystal region 151. The second electrode 172 overlaps one side perpendicular to one of the diffraction directions Ddif, among the four sides of the two-dimensional photonic crystal region 151 forming a boundary 155 between the two-dimensional photonic crystal region 151 and a non-two-dimensional photonic crystal region 152, by a predetermined width from the end on the non-two-dimensional photonic crystal region 152 side of the second electrode 172 to the boundary 155. The predetermined width is two times or more and ten times or less a period of the triangular lattice. This is because diffraction light of a secondary beam is extracted by using the outermost peripheral surface of a second medium 154 located near the outermost periphery of the two-dimensional photonic crystal region 151. If the second electrode 172 excessively protrudes outward from a boundary region, current injection loss occurs, and thus it is desirable that the second electrode 172 covers the boundary region by a width corresponding to approximately two periods to ten periods of the two-dimensional photonic crystal lattice.

In the electrode arrangement of FIG. 19, upon turning off supply of electricity to the first electrode 171 and turning on supply of electricity to the second electrode 172, a secondary beam 21 is generated in a corresponding one of the diffraction directions Ddif as illustrated in the FFP of FIG. 14.

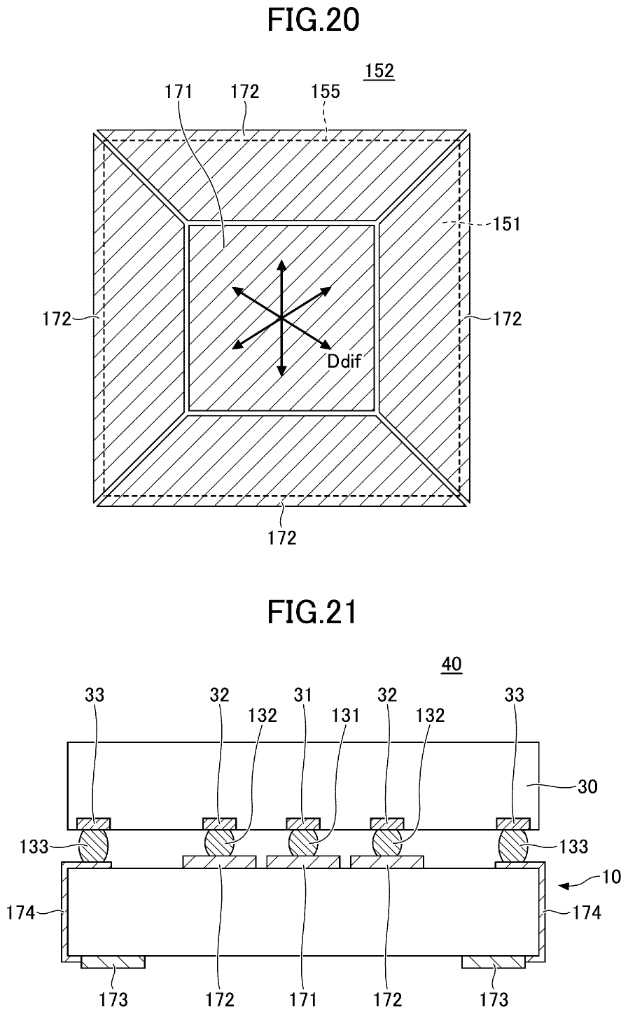

FIG. 20 is a diagram illustrating yet another example of the arrangement of electrodes for current injection. A first electrode 171 having a quadrangular shape is disposed at the center of the two-dimensional photonic crystal region 151 having the quadrangular shape. For convenience, the diffraction directions Ddif determined by the triangular lattice forming the two-dimensional photonic crystal region 151 are indicated by black arrows. Four second electrodes 172 separated from the first electrode 171 cover a region other than a central portion of the two-dimensional photonic crystal region 151. The four second electrodes 172 each having a trapezoidal shape in a plan view overlap the respective four sides of the two-dimensional photonic crystal region 151 by a predetermined width. The boundary 155 between the two-dimensional photonic crystal region 151 and the non-two-dimensional photonic crystal region 152 is substantially entirely covered by end portions on the bottom side of the four trapezoidal-shaped second electrodes 172.

In the electrode arrangement of FIG. 20, electricity is supplied to all of the first electrode 171 and the four second electrodes 172. As illustrated in the FFP of FIG. 8, in addition to diffraction light at the center, secondary beams 21 are generated in the vicinities of two sides that are orthogonal to corresponding ones of the diffraction directions Ddif determined by the triangular lattice, among the four sides forming the boundary 155.

In this manner, laser light can be emitted at desired position(s) by individually controlling supply of electricity to a plurality of electrodes electrically connected to a semiconductor layer having the two-dimensional photonic crystal region 151 of the semiconductor laser element 10. In a case where the two-dimensional periodic structure is a square lattice in the electrode arrangement of FIG. 20, in addition to diffraction light at the center, secondary beams are generated in four directions determined by the square lattice, that is, at four positions corresponding to the four sides of the quadrangular-shaped two-dimensional photonic crystal region 151. The greater the number of beams emitted, the higher the power of the entire emission light. By selectively emitting a specific secondary beam, a fine target can be individually irradiated.

### <Light Source Device Using Semiconductor Laser Element>

FIG. 21 is a schematic cross-sectional view of a light source device 40 using the semiconductor laser element 10 according to the embodiment. The light source device 40 includes the semiconductor laser element 10 described above and a circuit board 30 connected to the semiconductor laser element 10. The circuit board 30 includes a first terminal 31 connected to a first electrode 171 of the semiconductor laser element 10 and a second terminal 32 connected to a second electrode 172. This allows a primary beam and a secondary beam to be generated separately. In a case where the semiconductor laser element 10 includes two or more second electrodes 172 spaced apart from each other as illustrated in FIG. 20, the circuit board 30 includes the first terminal 31 connected to the first electrode 171 and a plurality of second terminals 32 connected to the two or more second electrodes 172, and the plurality of second terminals 32 are independent from each other. Accordingly, generation of secondary beams can be independently controlled. The plurality of second terminals 32 may be connected to the two or more second electrodes 172 in a one-to-one correspondence. Accordingly, whether or not to generate secondary beams can be individually and independently controlled. The first terminal 31 is connected to the first electrode 171 via an electrically-conductive bonding material 131. The second terminal 32 is connected to the second electrode 172 via an electrically-conductive bonding material 132.

A third electrode 173 provided on the surface of the semiconductor laser element 10 opposite to the first electrode 171 and the second electrode 172 may be connected to a third terminal 33 of the circuit board 30 via wiring 174. The third terminal 33 is connected to the wiring 174 via an electrically-conductive bonding material 133. The wiring 174 may be formed along the outer surface of the semiconductor laser element 10, or may be formed as a through via that penetrates the semiconductor laser element 10 in the layered direction. An insulating layer is provided between the semiconductor laser element 10 and the wiring 174. Alternatively, only the third electrode 173 need be connected to the third terminal 33 via a wire.

The circuit board 30 includes a current injection control circuit, and individually controls turning on and off of supply of electricity to the first electrode 171 and the second electrode 172 or turning on and off of supply of electricity to each of a plurality of second electrodes 172 via the first terminal 31, the second terminal 32, and the third terminal 33. The current injection control circuit may be implemented by a part of LSI mounted on the circuit board 30, or may be implemented by a logic device such as a field programmable gate array (FPGA). Accordingly, the light source device 40 that can output light in a desired direction with desired power can be achieved.

### <Process of Manufacturing Semiconductor Laser Element>

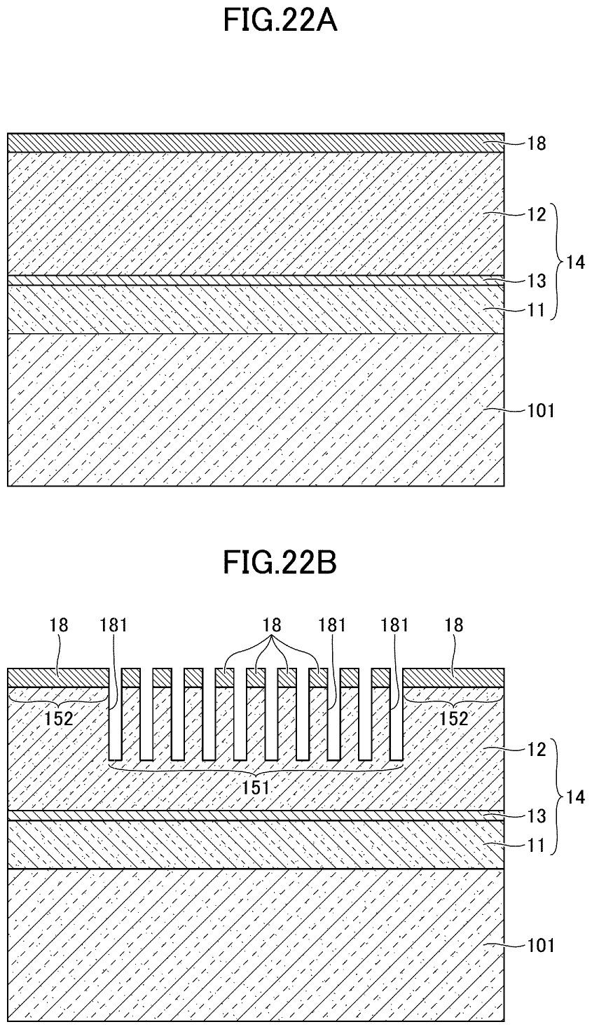

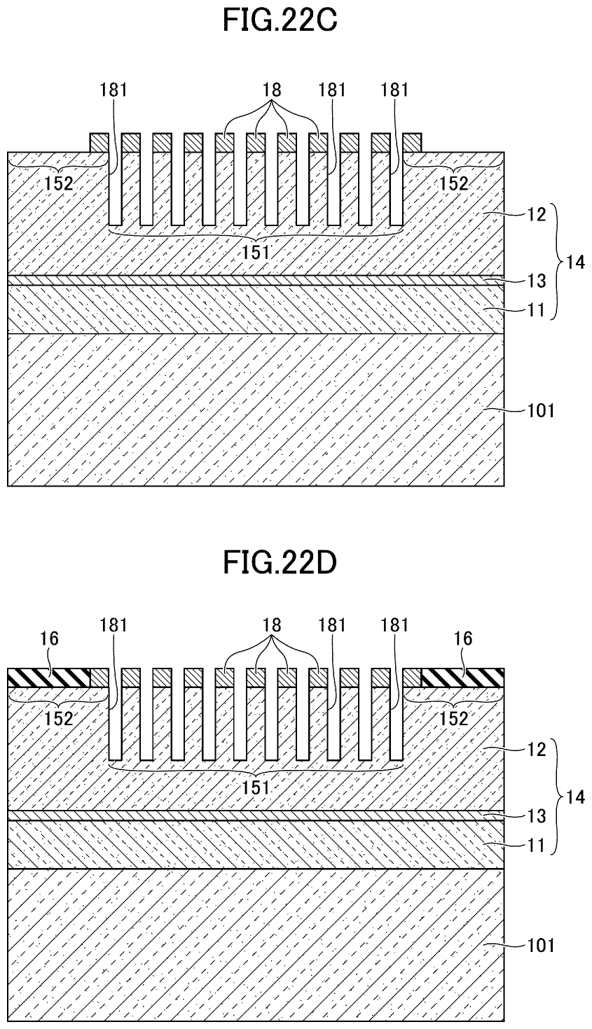

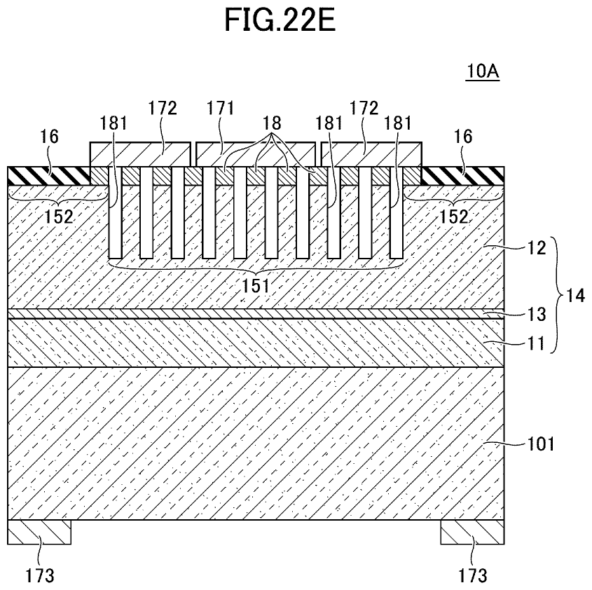

FIG. 22A to FIG. 22E illustrate an example of a process of manufacturing a semiconductor laser element. In FIG. 22A, a first semiconductor layer 11, an active layer 13, and a second semiconductor layer 12 are grown in this order on a substrate 101 to form a semiconductor layered body 14. The substrate 101 is, for example, a GaN substrate, and may contain an n-type impurity such as Si or Ge. The first semiconductor layer 11 is an n-side nitride semiconductor layer and is formed of AlₓGa₁₋ₓN (0≤x≤1). The first semiconductor layer 11 includes at least one or more n-type semiconductor layers. The first semiconductor layer 11 may include an n-side cladding layer on the side closer to the substrate 101 and an n-side optical guide layer on the side closer to the active layer 13. The active layer 13 has, for example, a single quantum well structure including one well layer and a plurality of barrier layers or a multiple quantum well structure including a plurality of well layers and a plurality of barrier layers. A material used for a well layer is, for example, GaN, InGaN, or AlGaN, and a material used for a barrier layer is, for example, AlGaN or GaN. A period of multiple quantum wells, and the thicknesses of well layers and barrier layers, may be appropriately designed according to a target wavelength.

After the active layer 13 is formed, the second semiconductor layer 12 is grown. The second semiconductor layer 12 is a p-side semiconductor layer. The refractive index of the first semiconductor layer 11 and the refractive index of the second semiconductor layer 12 are lower than the refractive index of the active layer 13. In a case where the first semiconductor layer 11, the active layer 13, and the second semiconductor layer 12 are formed of AlGaN-based materials, the Al composition ratio of each of the first semiconductor layer 11 and the second semiconductor layer 12 is set to be higher than the Al composition ratio of the active layer 13. In a case were the second semiconductor layer 12 includes a plurality of layers, a p-type impurity such as Mg may be added to a layer apart from the active layer 13. The second semiconductor layer 12 may include a p-side optical guide layer, an electron blocking layer, and a p-side cladding layer in order from the side closer to the active layer 13.

An electrically-conductive layer 18 is formed on the semiconductor layered body 14. As the electrically-conductive layer 18, a transparent electrically-conductive layer such as ITO, IZO, or IGZO may be formed by a sputtering method or the like. As the electrically-conductive layer 18, a nitride semiconductor layer containing a p-type impurity at a high concentration may be grown continuously from the semiconductor layered body 14.

In FIG. 22B, recesses 181 are formed in a two-dimensional periodic pattern in a predetermined region of the electrically-conductive layer 18 and the second semiconductor layer 12 by electron beam (EB) lithography and reactive ion etching (RIE). The recesses 181 are holes each having a shape of a cylinder or a polygonal prism, and each of the recesses 181 may have a depth reaching the vicinity of the active layer 13. A region including a periodic arrangement of the recesses 181 is a two-dimensional photonic crystal region 151. A region located outward of the two-dimensional photonic crystal region 151 and having no periodic structure is a non-two-dimensional photonic crystal region 152.

In FIG. 22C, the electrically-conductive layer 18 other than a current injection region is removed. The electrically-conductive layer 18 remaining in the current injection region including the two-dimensional photonic crystal region 151 may be used as a contact layer.

In FIG. 22D, an insulating layer 16 is formed on an exposed surface of the second semiconductor layer 12. The insulating layer 16 may be used as a protective layer. The insulating layer 16 may cover lateral surfaces of the substrate 101 and lateral surfaces of the semiconductor layered body 14. In FIG. 22E, a first electrodes 171 and a second electrode 172 are formed on the electrically-conductive layer 18 by a lift-off method or the like. Further, a third electrode 173 is formed on the back surface of the substrate 101, that is, the surface of the substrate 101 opposite to the semiconductor layered body 14. In this manner, a semiconductor laser element 10A is obtained.

In the semiconductor laser element 10 and the semiconductor laser element 10A according to the embodiments described above, supply of electricity to a plurality of electrodes can be individually controlled, and beams can be emitted in a plurality of directions by a single chip. A light source device using the semiconductor laser element 10 or 10A can individually control the output of secondary beams at different positions, and can emit beams in a plurality of directions by using the single semiconductor laser element 10 or 10A. The semiconductor laser elements and the light source device according to the embodiments can be applied to sensing, such as light detection and ranging (LiDAR), and a display.

Although specific example embodiments of the present disclosure have been described above, the present invention is not limited to the above-described example embodiments. The shape of a two-dimensional photonic crystal region 151 in a plan view is not limited to a quadrangular shape or a circular shape, and may be a polygonal shape such as a triangular shape or a hexagonal shape. A two-dimensional periodic structure formed in the two-dimensional photonic crystal region 151 is not limited to a square lattice or a triangular lattice, and may be a rectangular lattice, an oblique (parallelogram) lattice, a rhombic lattice, a hexagonal lattice, or the like. The shape of each second media 154 in a plan view, which are two-dimensionally and periodically arranged in a first medium 153, is not limited to a circular shape, and may be a polygonal shape such as a triangular shape, a quadrangular shape, or a hexagonal shape, or an elliptical shape. The shapes of a first electrode 171 and a second electrode 172 in a plan view may be appropriately designed according to a position from which diffraction light is to be emitted.

According to one embodiment of the present disclosure, a semiconductor laser element that can individually control turning secondary beams on or off is provided.

What is claimed is:

1. A semiconductor laser element comprising:
a semiconductor layered body comprising:
a first semiconductor layer on a first conductivity side,
a second semiconductor layer on a conductivity side opposite to the first conductivity side, and
an active layer disposed between the first semiconductor layer and the second semiconductor layer;
a first electrode and a second electrode that are separated from each other and electrically connected to the second semiconductor layer; and
a third electrode electrically connected the first semiconductor layer, wherein:
one or both of the first semiconductor layer and the second semiconductor layer have a two-dimensional photonic crystal region and a non-two-dimensional photonic crystal region,
the two-dimensional photonic crystal region has a two-dimensional periodic structure in which, in a first medium having a first refractive index, second media having a second refractive index different from the first refractive index are two-dimensionally and periodically arranged,
the non-two-dimensional photonic crystal region does not have a periodic structure and is disposed outward of the two-dimensional photonic crystal region,
the first electrode is located inward of the two-dimensional photonic crystal region in a plan view, and
the second electrode overlaps, among boundary regions defining a boundary between the two-dimensional photonic crystal region and the non-two-dimensional photonic crystal region, at least a boundary region that is orthogonal to one of diffraction directions determined by the two-dimensional periodic structure.

2. The semiconductor laser element according to claim 1, wherein:
the first semiconductor layer is an n-side semiconductor layer,
the second semiconductor layer is a p-side semiconductor layer,
the first electrode is a first positive electrode,
the second electrode is a second positive electrode,
the third electrode is a negative electrode, and
the p-side semiconductor layer has the two-dimensional photonic crystal region and the non-two-dimensional photonic crystal region.

3. The semiconductor laser element according to claim 1, wherein:
the second electrode comprises two or more second electrodes spaced apart from each other, and
the two or more second electrodes overlap boundary regions that are orthogonal to respective ones of the diffraction directions determined by the two-dimensional periodic structure.

4. The semiconductor laser element according to claim 1, wherein the second electrode overlaps the two-dimensional photonic crystal region at a location outward of the first electrode as viewed from a center of the two-dimensional photonic crystal region.

5. The semiconductor laser element according to claim 1, wherein:
the second electrode overlaps the non-two-dimensional photonic crystal region by a predetermined width from the boundary region, and
the predetermined width is two times or more and ten times or less a period of the two-dimensional periodic structure.

6. The semiconductor laser element according to claim 1, wherein the two-dimensional periodic structure of the two-dimensional photonic crystal region is a square lattice structure or a triangular lattice structure.

7. The semiconductor laser element according to claim 6, wherein:
the two-dimensional periodic structure is the triangular lattice structure, and
the two-dimensional photonic crystal region is a circle having a circumference to which a tangent line orthogonal to one of diffraction directions determined by a triangular lattice is drawable, or a polygon having a side orthogonal to one of the diffraction directions determined by the triangular lattice.

8. The semiconductor laser element according to claim 6, wherein:
the two-dimensional periodic structure is the square lattice structure, and
the two-dimensional photonic crystal region is a circle having a circumference to which a tangent line is orthogonal to one of diffraction directions determined by a square lattice, or a polygon having a side orthogonal to one of the diffraction directions determined by the square lattice.

9. The semiconductor laser element according to claim 1, wherein the first semiconductor layer, the active layer, and the second semiconductor layer are nitride semiconductor layers.

10. A light source device comprising:
the semiconductor laser element of claim 1; and
a circuit board connected to the semiconductor laser element, wherein:
the circuit board comprises:
a first terminal connected to the first electrode, and
a second terminal connected to the second electrode.

11. A light source device comprising:
the semiconductor laser element of claim 3; and
a circuit board connected to the semiconductor laser element, wherein:
the circuit board comprises:
a first terminal connected to the first electrode, and
a plurality of second terminals connected to the two or more second electrodes, and
the plurality of second terminals are independent from each other.

12. The light source device according to claim 11, wherein each of the plurality of second terminals is connected to a respective one of the two or more second electrodes.
